(19) United States
(12) Patent Application Publication
(10) Pub. No.: US 2008/0223399 A1
(43) Pub. Date: Sep. 18, 2008

(54) SUBSTRATE PROCESSING APPARATUS, SUBSTRATE PROCESSING METHOD AND STORAGE MEDIUM

(75) Inventor: Tadashi ONISHI, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 12/047,649

(22) Filed: Mar. 13, 2008

Related U.S. Application Data
(60) Provisional application No. 60/938,722, filed on May 18, 2007.

(30) Foreign Application Priority Data
Mar. 16, 2007 (JP) 2007-068127

(51) Int. Cl. B08B 7/00; H01L 21/67; B08B 13/00; H01L 21/302

(52) U.S. Cl. 134/1.3; 134/102.1; 257/E21.214

(57) ABSTRACT

A substrate processing apparatus includes: a mounting table to have the substrate placed thereon in a process chamber; a first temperature adjusting mechanism temperature-adjusting the substrate placed on the mounting table; a lifter mechanism lifting up the substrate from the mounting table in the process chamber; and a second temperature adjusting mechanism temperature-adjusting the substrate lifted up from the mounting table by the lifter mechanism, wherein the first temperature adjusting mechanism and the second temperature adjusting mechanism temperature-adjust the substrate to different temperatures respectively.

### BACKGROUND OF THE INVENTION

1. Field of the Invention

The present invention relates to a substrate processing apparatus, a substrate processing method, and a storage medium.

2. Description of the Related Art

In manufacturing processes of semiconductor devices, for instance, various processing steps are performed while the inside of a process chamber housing a semiconductor wafer (hereinafter, referred to as a “wafer”) is set in a low-pressure state close to a vacuum state. As an example of the processing utilizing such a low-pressure state, there has been know COR (Chemical Oxide Removal) processing for chemically removing an oxide film (silicon dioxide (SiO₂)) existing on a surface of a wafer (see, the specification of US Patent Application Publication No. 2004/0182417 and the specification of US Patent Application Publication No. 2004/0184792). In this COR processing, under the low-pressure state, mixed gas of hydrogen fluoride gas (HF) and ammonia gas (NH₃) is supplied while the temperature of the wafer is adjusted to a predetermined value, thereby turning the oxide film into a reaction product mainly containing ammonium fluorosilicate, and then the reaction product is vaporized (sublimated) by heating to be removed from the wafer.

### SUMMARY OF THE INVENTION

As an apparatus for such COR processing, there has been generally known an apparatus including: a chemical processing chamber in which the step of turning an oxide film on a surface of a wafer into a reaction product is performed under a relatively low temperature; and a heat treatment chamber in which the step of removing the reaction product from the wafer by heating and sublimating the reaction product is performed under a relatively high temperature. However, such a processing apparatus in which the chemical processing chamber and the heat treatment chamber are separately provided has a disadvantage that the apparatus becomes large, leading to an increase in footprint since the number of process chambers increases. Further, separately providing the chemical processing chamber and the heat treatment chamber necessitates the transfer of a wafer therebetween, which requires a complicated carrier mechanism and further may cause a problem that during the transfer, the wafer is contaminated and contaminants are released from the wafer.

The present invention was made in view of the above and its object is to provide a substrate processing apparatus and a substrate processing method capable of rapidly heating and cooling a substrate in the same process chamber.

To solve the above problems, according to the present invention, there is provided a substrate processing apparatus processing a substrate in a process chamber, the apparatus including: a mounting table to have the substrate placed thereon in the process chamber; a first temperature adjusting mechanism adjusting the temperature of the substrate placed on the mounting table; a lifter mechanism lifting up the substrate from the mounting table in the process chamber; and a second temperature adjusting mechanism adjusting the temperature of the substrate which has been lifted up from the mounting table by the lifter mechanism, wherein the first temperature adjusting mechanism and the second temperature adjusting mechanism adjust the substrate to different temperatures respectively.

This substrate processing apparatus may have an exhaust mechanism exhausting the inside of the process chamber. In this case, the substrate apparatus may further include: a partition member disposed around the substrate which has been lifted up from the mounting table by the lifter mechanism; a first exhaust mechanism exhausting the inside of the process chamber above the partition member; and a second exhaust mechanism exhausting the inside of the process chamber under the partition member. The substrate processing apparatus may further include a gas supply mechanism supplying predetermined gas to the inside of the process chamber. In this case, the gas supply mechanism may supply the predetermined gas to the inside of the process chamber above the substrate which has been lifted up from the mounting table by the lifter mechanism.

Further, according to the present invention, there is provided a substrate processing method of processing a substrate in a process chamber, the method including the steps of: placing the substrate on a mounting table to process the substrate while adjusting the temperature of the substrate by a first temperature adjusting mechanism; and lifting up the substrate from the mounting table in the process chamber to process the substrate while adjusting the temperature of the substrate by a second temperature adjusting mechanism, wherein the first temperature adjusting mechanism and the second temperature adjusting mechanism adjust the substrate to different temperatures respectively.

Further, according to the present invention, there is provided a storage medium containing a recorded program executable by a control unit of a substrate processing apparatus, the program causing the substrate processing apparatus to perform the above substrate processing method when executed by the control unit.

According to the present invention, the state in which the substrate is placed on the mounting table and processed in the process chamber while being temperature-adjusted by the first temperature adjusting mechanism and the state in which the substrate is lifted up from the mounting table and processed in the process chamber while being temperature-adjusted by the second temperature adjusting mechanism are switched, which enables rapid heating and cooling of the substrate. Accordingly, since low-temperature processing and high-temperature processing of the substrate can be performed in the same process chamber, the apparatus can be compact and a complicated transfer sequence for substrate transfer is not required.

### BRIEF DESCRIPTION OF THE DRAWINGS

FIG. 1 is a plane view showing a rough configuration of a processing system;

FIG. 2 is an explanatory view of a COR apparatus, showing a state where a wafer is placed on a mounting table (first processing position);

FIG. 3 is an explanatory view of the COR apparatus, showing a state where the wafer is lifted up from the mounting table (second processing position);

FIG. 4 is a rough vertical sectional view showing the structure of a surface of the wafer before a Si layer is etched;

FIG. 5 is a rough vertical sectional view showing the structure of the surface of the wafer after the Si layer is etched;

FIG. 6 is a rough vertical sectional view showing a state of the surface of the wafer after the wafer undergoes COR processing; and

FIG. 7 is a rough vertical sectional view showing a state of the surface of the wafer after the wafer undergoes film forming processing for forming a SiGe layer.

### DETAILED DESCRIPTION OF THE INVENTION

Hereinafter, an embodiment of the present invention will be described in which an oxide film (silicon dioxide (SiO₂)) formed on a surface of a semiconductor wafer (hereinafter, referred to as a “wafer”) is removed by COR processing as an example of substrate processing. In the specification and drawings, constituent elements having substantially the same functions and structures are denoted by the same reference numerals and symbols, and redundant description thereof will be omitted.

### (Overall Description of Processing System)

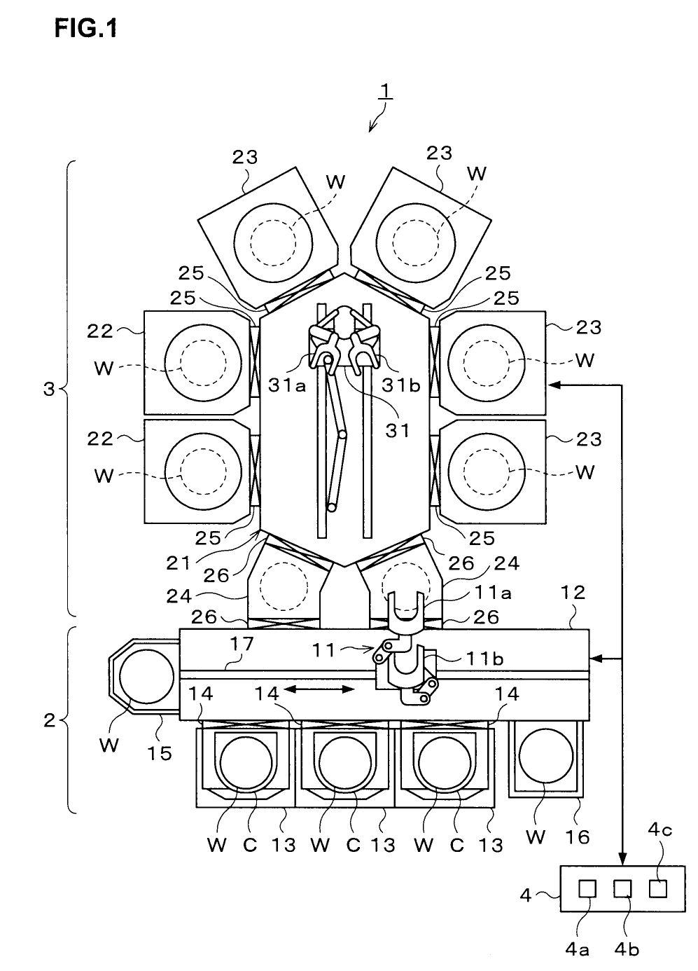

FIG. 1 is a plane view showing a rough configuration of a processing system 1 including COR apparatuses 22 according to the embodiment of the present invention. The processing system 1 is configured to apply COR (Chemical Oxide Removal) processing and film forming processing to a wafer W as an example of a substrate to be processed. In the COR processing, chemical processing to turn a natural oxide film on a surface of the wafer W into a reaction product and heat treatment to heat and sublimate the reaction product are performed. In the chemical processing, gas containing a halogen element and basic gas are supplied as process gases to the wafer W, thereby causing a chemical reaction of the natural oxide film on the surface of the wafer W and gas molecules of the process gases, so that the reaction product is produced. The gas containing the halogen element is, for example, hydrogen fluoride gas and the basic gas is, for example, ammonia gas. In this case, the natural oxide film on the surface of the wafer W is turned into the reaction product mainly containing ammonia fluorosilicate. The heat treatment is PHT (Post Heat Treatment) to heat the wafer W having undergone the chemical processing to vaporize the reaction product, thereby removing the reaction product from the wafer W. In the film forming processing, a film of SiGe or the like, for instance, is epitaxially grown on the surface of the wafer W from which the natural oxide film has been removed.

The processing system 1 shown in FIG. 1 includes: a load/unload unit 2 loading/unloading the wafer W to/from the processing system 1; a processing unit 3 applying the COR processing and the film forming processing to the wafer W; and a control unit 4 controlling the load/unload unit 2 and the processing unit 3.

The load/unload unit 2 has a carrier chamber 12 in which a first wafer carrier mechanism 11 carrying the wafer W in a substantially disk shape is provided. The wafer carrier mechanism 11 has two carrier arms 11a, 11b each holding the wafer W in a substantially horizontal state. On a side of the carrier chamber 12, there are, for example, three mounting tables 13 on which carriers C each capable of housing the plural wafers W are mounted. In each of the carriers C, the maximum of, for example, 25 pieces of the wafers W can be horizontally housed in multi tiers at equal pitches, and the inside of the carriers C is filled with an N₂ gas atmosphere, for instance. Between the carriers C and the carrier chamber 12, gate valves 14 are disposed, and the wafer W is transferred between the carriers C and the carrier chamber 12 via the gate valves 14. On sides of the mounting tables 13, provided are: an orienter 15 which rotates the wafer W and optically calculates its eccentricity amount to align the wafer W; and a particle monitor 16 measuring an amount of particles of extraneous matters and the like adhering on the wafer W. In the carrier chamber 12, a rail 17 is provided, and the wafer carrier mechanism 11 is capable of approaching the carriers C, the orienter 15, and the particle monitor 16 by moving along the rail 17.

In the load/unload unit 2, the wafer W is horizontally held by either of the carrier arms 11a, 11b of the wafer carrier mechanism 11, and when the wafer carrier mechanism 11 is driven, the wafer W is rotated and moved straight in a substantially horizontal plane or lifted up/down. Consequently, the wafer W is carried to/from the carriers C, the orienter 15, and the particle monitor 16 from/to later-described two load lock chamber 24.

At the center of the processing unit 3, a common carrier chamber 21 formed in a substantially polygonal shape (for example, a hexagonal shape) is provided. In the shown example, two COR apparatuses 22 applying the COR processing to the wafer W, four epitaxial growth apparatuses 23 applying the SiGe layer film forming processing to the wafer W, and the two load lock chambers 24 which can be evacuated are provided around the common carrier chamber 21. Between the common carrier chamber 21 and the COR apparatuses 22 and between the common carrier chamber 21 and the epitaxial growth apparatuses 23, openable/closable gate vales 25 are provided respectively.

The two load lock chambers 24 are disposed between the carrier chamber 12 of the load/unload unit 2 and the common carrier chamber 21 of the processing unit 3, and the carrier chamber 12 of the load/unload unit 2 and the common carrier chamber 21 of the processing unit 3 are coupled to each other via the two load lock chambers 24. Openable/closable gate valves 26 are provided between the load lock chambers 24 and the carrier chamber 12 and between the load lock chambers 24 and the common carrier chamber 21. One of the two load lock chambers 24 may be used when the wafer W is carried out of the carrier chamber 12 to be carried into the common carrier chamber 21, and the other may be used when the wafer W is carried out of the common carrier chamber 21 to be carried into the carrier chamber 12.

A second wafer carrier mechanism 31 carrying the wafer W is provided in the common carrier chamber 21. The wafer carrier mechanism 31 has two carrier arms 31a, 31b each holding the wafer W in a substantially horizontal state.

In such a common carrier chamber 21, the wafer W is horizontally held by either of the carrier arms 31a, 31b, and when the wafer carrier mechanism 31 is driven, the wafer W is rotated and moved straight in a substantially horizontal plane or lifted up/down to be carried to a desired position. Then, by the carrier arms 31a, 31b entering and exiting from the load lock chambers 24, the COR apparatuses 22, and the epitaxial growth apparatuses 23, the wafers W are loaded/unloaded thereto/therefrom.

### (Structure of COR Apparatus)

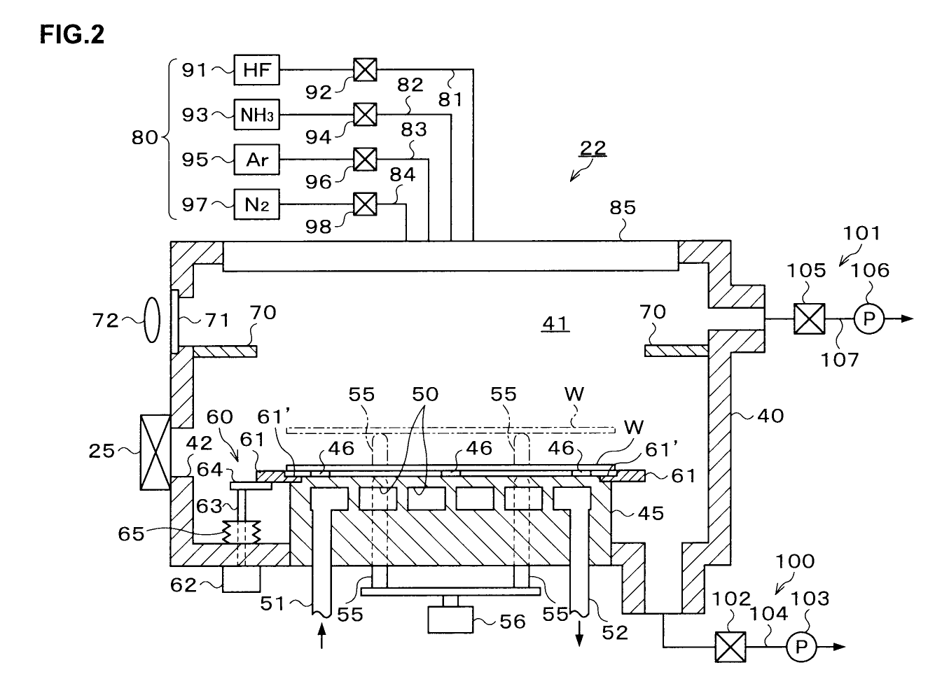

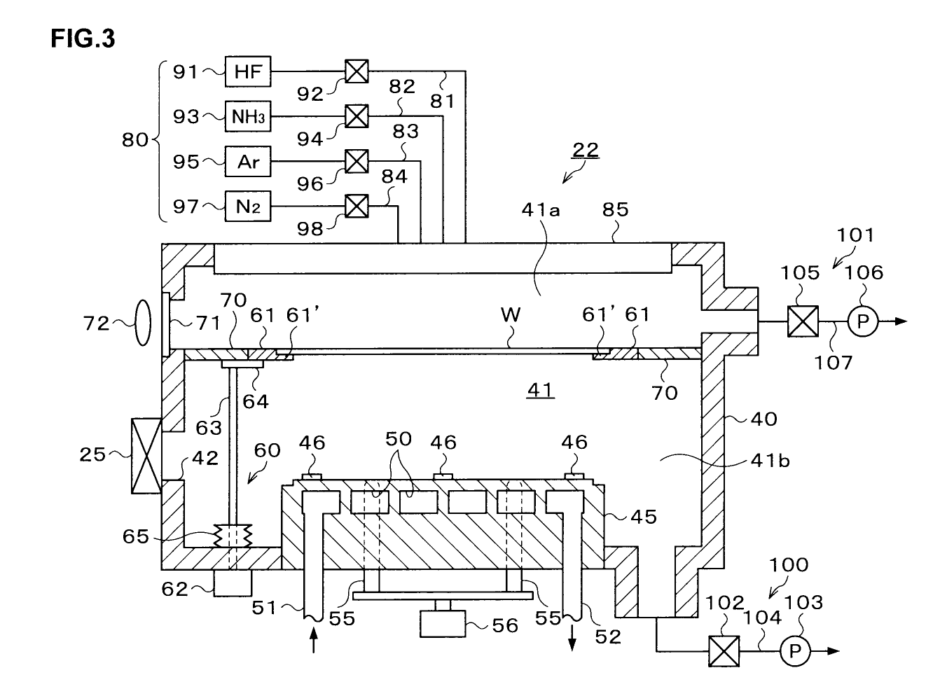

FIG. 2 and FIG. 3 are explanatory views of the COR apparatus 22 according to the embodiment of the present invention. FIG. 2 shows a state where the wafer W is placed on a mounting table 45 (first processing position). FIG. 3 shows a state where the wafer W is lifted up from the mounting table 45 (second processing position).

The COR apparatus 22 includes a casing 40, and the inside of the casing 40 is an airtight process chamber (processing space) 41 housing the wafer W. The casing 40 is made of metal such as aluminum (Al) or an aluminum alloy which has been surface-treated, for instance, anodized. The casing 40 has on its one side surface a load/unload port 42 through which the wafer W is loaded/unloaded to/from the process chamber 41, and the aforesaid gate valve 25 is provided on the load/unload port 42.

On a bottom of the process chamber 41, the mounting table 45 is provided to have the wafer W placed thereon in a substantially horizontal state. The mounting table 45 has a columnar shape substantially equal in diameter to the wafer W and is made of a material excellent in heat transfer property, for example, metal such as aluminum (Al) or an aluminum alloy.

On an upper surface of the mounting table 45, a plurality of abutting pins 46 as abutting members abutting on a lower surface of the wafer W are provided so as to protrude upward. The abutting pins 46 are made of the same material as that of the mounting table 45 or made of ceramics, resin, or the like. The wafer W is supported substantially horizontally on the upper surface of the mounting table 45 while a plurality of points of its lower surface are set on upper end portions of the abutting pins 46 respectively. For convenience of the description, the position (height) of the wafer W placed on the upper surface of the mounting table 45 as shown in FIG. 2 is defined as the “first processing position”.

In the mounting table 45, a refrigerant channel 50 as a first temperature adjusting mechanism is provided. By circulatingly supplying a refrigerant to the refrigerant channel 50 from the outside of the casing 40 through a refrigerant feed pipe 51 and a refrigerant drain pipe 52, it is possible to cool the mounting table 45 to about 25° C., for instance. A refrigerant such as, for example, a fluorine-based inert chemical solution (Galden) is supplied to the refrigerant channel 50.

In the mounting table 45, lifter pins 55 are provided which receive/deliver the wafer W from/to either of the carrier arms 31a, 31b of the aforesaid wafer carrier mechanism 31 when the wafer W is loaded/unloaded. The lifter pins 55 move up/down by the operation of a cylinder device 56 disposed outside the casing 40. When the wafer W is carried into the COR apparatus 22 by either of the carrier arms 31a, 31b of the aforesaid wafer carrier mechanism 31, the lifter pins 55 move up so that the upper ends thereof reach the height of the load/unload port 42 as shown by the dashed line in FIG. 2, to receive the wafer W from the carrier arm 31a, 31b, and thereafter, the lifter pins 55 move down, so that the wafer W is placed on the upper surface of the mounting table 45. Further, when the wafer W is to be carried out of the COR apparatus 22, the lifter pins 55 first move up, so that the wafer W is lifted up to the height of the load/unload port 42 as shown by the dashed line in FIG. 2. Thereafter, either of the carrier arms 31a, 31b of the aforesaid wafer carrier mechanism 31 receives the wafer W from the lifter pins 55 to carry the wafer W out of the COR apparatus 22. For convenience of the description, the position (height) of the wafer W lifted up to the height of the load/unload port 42 by the lifter pins 55 is defined as a “load/unload position”.

Further, around the wafer W, a lifter mechanism 60 is provided to lift the wafer W placed on the upper surface of the mounting table 45 up to a position still higher than the aforesaid load/unload position. The lifter mechanism 60 is structured such that a ring-shaped support member 61 surrounding an outer side of the wafer W is attached via a bracket 64 to an upper end of a piston rod 63 of the cylinder device 62 disposed outside the casing 40. By the extension/contraction operation of the cylinder device 62, it is possible to change between the state where the wafer W is placed on the mounting table 45 as shown in FIG. 2 and the state where the wafer W is lifted up from the mounting table 45 as shown in FIG. 3. Around the piston rod 63, a bellows 65 is attached to allow the upward/downward movement of the piston rod 63 while keeping the inside of the process chamber 41 airtight.

On an inner side of an upper surface of the support member 61, a stepped portion 61′ capable of housing an outer edge portion of the lower surface of the wafer W is formed, and when the piston rod 63 is extended by the operation of the cylinder device 62, the wafer W is lifted up to the position still higher than the load/unload position while the outer edge portion of the lower surface of the wafer W is housed in the stepped portion 61′ of the support member 61, as shown in FIG. 3. For convenience of the description, the position (height) of the wafer W lifted up from the upper surface of the mounting table 45 by the lifter mechanism 60 as shown in FIG. 3 is defined as the “second processing position”.

On the other hand, when the piston rod 63 is contracted by the operation of the cylinder device 62, the stepped portion 61′ of the support member 61 moves down so that the stepped portion 61′ is positioned slightly lower than the upper ends of the abutting pins 46 on the upper surface of the mounting table 45, and consequently, the wafer W comes to be supported by the abutting pins 46 on the upper surface of the mounting table 45 (first processing position).

Around the wafer W lifted up to the second processing position by the lifter mechanism 60 as shown in FIG. 3, a partition member 70 is disposed. The partition member 70 is fixed to an inner peripheral surface of the casing 40 and is horizontally disposed so as to partition an area around the support member 61 which has been lifted up to the second processing position while the outer edge portion of the lower surface of the wafer W is housed in the stepped portion 61′. The partition member 70 is made of a heat insulating material such as, for example, VESPEL (registered trademark). When the wafer W is lifted up to the second processing position by the lifter mechanism 60 as shown in FIG. 3, the wafer W, the support member 61, and the partition member 70 partition the inside of the process chamber 41 into a space 41a above the wafer W and a space 41b under the wafer W.

Above the partition member 70, the casing 40 has, on its side surface, a transparent window portion 71. Further, a lamp heater 72 as a second temperature adjusting mechanism is disposed on an outer side of the window portion 71 to emit infrared rays from the outside of the process chamber 41 into the process chamber 41 through the window portion 71. As will be described later, when the wafer W is lifted up to the second processing position by the lifter mechanism 60, the infrared rays are emitted into the process chamber 41 from the lamp heater 72 through the window portion 71, so that the wafer W at the second processing position is heated.

A gas supply mechanism 80 supplying predetermined gases into the process chamber 41 is provided. The gas supply mechanism 80 includes an HF supply path 81 through which hydrogen fluoride gas (HF) as the process gas containing the halogen element is supplied into the process chamber 41, an NH₃ supply path 82 through which ammonia gas (NH₃) as the basic gas is supplied into the process chamber 41, an Ar supply path 83 through which argon gas (Ar) as inert gas is supplied into the process chamber 41, an N₂ supply path 84 through which nitrogen gas (N₂) as inert gas is supplied into the process chamber 41, and a showerhead 85. The HF supply path 81 is connected to a supply source 91 of the hydrogen fluoride gas. Further, the HF supply path 81 has in its middle a flow rate regulating valve 92 capable of opening/closing the HF supply path 81 and adjusting a supply flow rate of the hydrogen fluoride gas. The NH₃ supply path 82 is connected to a supply source 93 of the ammonia gas. Further, the NH₃ supply path 82 has in its middle a flow rate regulating valve 94 capable of opening/closing the NH₃ supply path 82 and adjusting a supply flow rate of the ammonia gas. The Ar supply path 83 is connected to a supply source 95 of the argon gas. Further, the Ar supply path 83 has in its middle a flow rate regulating valve 96 capable of opening/closing the Ar supply path 83 and adjusting a supply flow rate of the argon gas. The N₂ supply path 84 is connected to a supply source 97 of the nitrogen gas. Further, the N₂ supply path 84 has in its middle a flow rate regulating valve 98 capable of opening/closing the N₂ supply path 84 and adjusting a supply flow rate of the nitrogen gas. The supply paths 81, 82, 83, 84 are connected to the showerhead 85 provided in a ceiling portion of the process chamber 41, and the hydrogen fluoride gas, the ammonia gas, the argon gas, and the nitrogen gas are diffusively jetted from the showerhead 85 into the process chamber 41.

In the COR apparatus 22, provided are: a first exhaust mechanism 100 exhausting the inside of the process chamber 41 under the aforesaid partition member 70; and a second exhaust mechanism 101 exhausting the inside of the process chamber 41 above the partition member 70. The first exhaust mechanism 100 includes an exhaust path 104 having in its middle an opening/closing valve 102 and an exhaust pump 103 for forced exhaust. An upstream end portion of the exhaust path 104 is opened at a bottom surface of the casing 40. The second exhaust mechanism 101 includes an exhaust path 107 having in its middle an opening/closing valve 105 and an exhaust pump 106 for forced exhaust. An upstream end portion of the exhaust path 107 is opened at a side surface of the casing 40 above the partition member 70.

### (Control Unit)

The functional elements of the processing system 1 and the COR apparatuses 22 are connected via signal lines to the control unit 4 automatically controlling the operation of the whole processing system 1. Here, the functional elements refer to all the elements which operate for realizing predetermined process conditions, such as, for example, the aforesaid first wafer carrier mechanism 11, gate valves 14, 25, 26, second wafer carrier mechanism 31, refrigerant supply to the mounting table 45, cylinder device 56, lifter mechanism 60, lamp heater 72, gas supply mechanism 80, exhaust mechanisms 100, 101, and so on. The control unit 4 is typically a general-purpose computer capable of realizing an arbitrary function depending on software that it executes.

As shown in FIG. 1, the control unit 4 has an arithmetic part 4a including a CPU (central processing unit), an input/output part 4b connected to the arithmetic part 4a, and a storage medium 4c storing control software and inserted in the input/output part 4b. The control software recorded in the storage medium 4c causes the processing system 1 to perform a predetermined substrate processing method to be described later when executed by the control unit 4. By executing the control software, the control unit 4 controls the functional elements of the processing system 1 so that various process conditions (for example, pressure of the process chamber 41 and so on) defined by a predetermined process recipe are realized.

The storage medium 4c may be the one fixedly provided in the control unit 4, or may be the one removably inserted in a not-shown reader provided in the control unit 4 and readable by the reader. In the most typical embodiment, the storage medium 4c is a hard disk drive in which the control software has been installed by a serviceman of a maker of the processing system 1. In another embodiment, the storage medium 4c is a removable disk such as CD-ROM or DVD-ROM in which the control software is written. Such a removable disk is read by an optical reader (not shown) provided in the control unit 4. Further, the storage medium 4c may be either of a RAM (random access memory) type or a ROM (read only memory) type. Further, the storage medium 4c may be a cassette-type ROM. In short, any medium known in a computer technical field is usable as the storage medium 4c. In a factory where the plural processing systems 1 are disposed, the control software may be stored in a management computer centrally controlling the control units 4 of the processing systems 1. In this case, each of the processing systems 1 is operated by the management computer via a communication line to execute a predetermined process.

### (Processing of Wafer)

Next, an example of the method of processing the wafer W using the processing system 1 as configured above will be described. To begin with, the structure of the wafer W processed by the processing method according to the embodiment of the present invention will be described. The following will describe a case, as an example, where natural oxide films 156 formed on the surface of the wafer W having undergone an etching process are removed by the COR processing, and SiGe is epitaxially grown on a surface of a Si layer 150. It should be noted that the structure of the wafer W and the processing of the wafer W described below are only an example, and the present invention is not limited to the embodiment below.

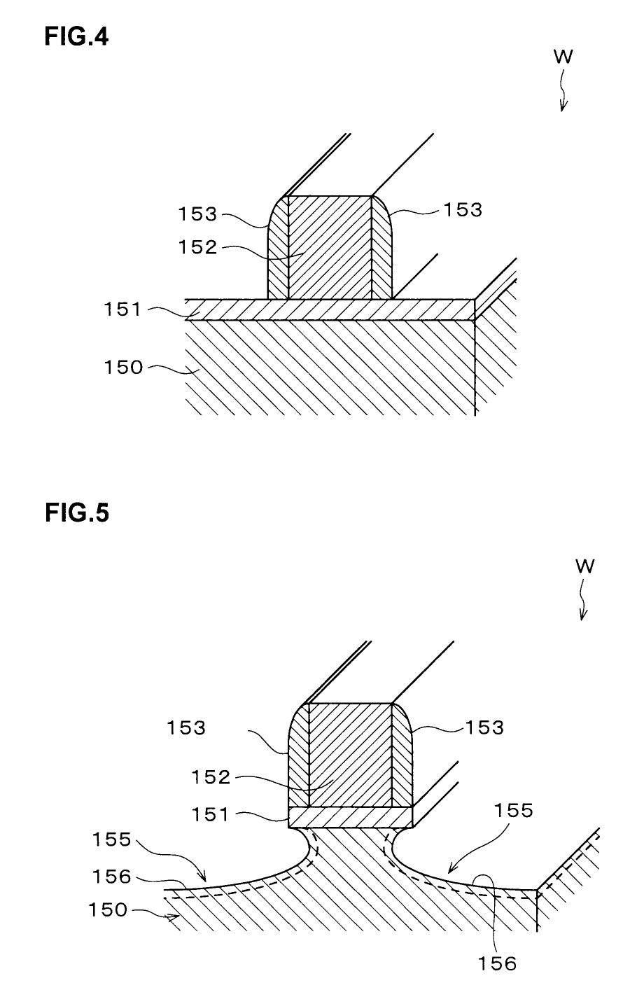

FIG. 4 is a rough sectional view of the wafer W which has not yet undergone the etching process, showing part of the surface of the wafer W (device formation surface). The wafer W is, for example, a thin-plate silicon wafer formed in a substantially disk shape, and on the surface of the wafer W, formed is a structure composed of the Si (silicon) layer 150 as a base material of the wafer W, an oxide layer (silicon dioxide: SiO₂) 151 used as an interlayer insulation layer, a Poly-Si (polycrystalline silicon) layer 152 used as a gate electrode, and, for example, TEOS (tetraethylorthosiicate: Si(OC₂H₅)₄) layers 153 as sidewall portions made of an insulator. A surface (upper surface) of the Si layer 150 is substantially flat, and the oxide layer 151 is stacked to cover the surface of the Si layer 150. Further, the oxide layer 151 is formed in, for example, a diffusion furnace through a thermal CVD reaction. The Poly-Si layer 152 is formed on a surface of the oxide layer 151 and is etched along a predetermined pattern shape. Therefore, some portions of the oxide layer 151 are covered by the Poly-Si layer 152, and other portions thereof are exposed. The TEOS layers 153 are formed to cover side surfaces of the Poly-Si layer 152. In the shown example, the Poly-Si layer 152 has a substantially prismatic cross section and is formed in a long and thin plate shape extending in a direction from the near side toward the far side in FIG. 4, and the TEOS layers 153 are provided on the right and left side surfaces of the Poly-Si layer 12 to extend along the direction from the near side toward the far side and to cover the Poly-Si layer 152 from its lower edge to upper edge. On the right and left sides of the Poly-Si layer 152 and the TEOS layers 153, the surface of the oxide layer 151 is exposed.

FIG. 5 shows a state of the wafer W having undergone the etching process. After the oxide layer 151, the Poly-Si layer 152, the TEOS layers 153, and so on are formed on the Si layer 150 as shown in FIG. 4, the wafer W is subjected to, for example, dry etching. Consequently, as shown in FIG. 5, on the surface of the wafer W, the exposed oxide layer 151 and the Si layer 150 covered by the oxide layer 151 are partly removed. Specifically, on the right and left sides of the Poly-Si layer 152 and the TEOS layers 153, recessed portions 155 are formed respectively by the etching. The recessed portions 155 are formed so as to sink into the Si layer 150 from the height of the surface of the oxide layer 151, and the Si layer 150 is exposed on inner surfaces of the recessed portions 155. However, if oxygen in the atmosphere adheres to the surface of the Si layer 150 thus exposed in the recessed portions 155, the natural oxide films (silicon dioxide: SiO₂) 156 are formed on the inner surfaces of the recessed portions 155 since the Si layer 150 is easily oxidized.

The wafer W thus subjected to the etching process by a dry etching apparatus (not shown) or the like and having the natural oxide films 156 formed on the inner surfaces of the recessed portions 155 as shown in FIG. 5 is housed in the carrier C to be carried to the processing system 1.

In the processing system 1, as shown in FIG. 1, the carrier C housing the plural wafers W is placed on the mounting table 13, and one of the wafers W is taken out of the carrier C by the wafer carrier mechanism 11 to be carried into the load lock chamber 24. When the wafer W is carried into the load lock chamber 24, the load lock chamber 24 is airtightly closed and pressure-reduced. Thereafter, the load lock chamber 24 and the common carrier chamber 21 whose pressure is reduced below the atmospheric pressure are made to communicate with each other. Then, the wafer W is carried out of the load lock chamber 24 to be carried into the common carrier chamber 21 by the wafer carrier mechanism 31.

The wafer W carried into the common carrier chamber 21 is first carried into the process chamber 41 of the COR apparatus 22. The wafer W is carried into the process chamber 41 by either of the carrier arms 31a, 31b of the wafer carrier mechanism 31, with its surface (device formation surface) facing upward. Then, the lifter pins 55 move up and receive the wafer W from the carrier arm 31a, 31b which has lifted up the wafer W to the load/unload position. Thereafter, the lifter pins 55 move down to place the wafer W on the upper surface of the mounting table 45, so that the wafer W is moved to the first processing position as shown in FIG. 2.

After the carrier arm 31a, 31b exits from the inside of the process chamber 41, the load/unload port 42 is closed to make the inside of the process chamber 41 airtight. Incidentally, when the wafer W is thus carried into the process chamber 41, the support member 61 is in a lowered state. Further, the pressure of the process chamber 41 has been reduced to a pressure close to vacuum (for example, several Torr to several tens Torr) by both of the exhaust mechanisms 100, 101 or one of the exhaust mechanisms 100, 101.

Then, the refrigerant is circulatingly supplied to the refrigerant channel 50 through the refrigerant feed pipe 51 and the refrigerant drain pipe 52 to cool the mounting table 45 to about 25° C., for instance. In this case, by starting the supply of the refrigerant before the wafer W is placed on the mounting table 45, it is possible to cool the wafer W to a target temperature immediately after the wafer W is placed on the upper surface of the mounting table 45.

Then, the hydrogen fluoride gas, the ammonia gas, the argon gas, and the nitrogen gas are supplied into the process chamber 41 through the respective supply paths 81, 82, 83, 84, and the wafer W at the first processing position is subjected to the chemical processing for turning the natural oxide films 156 on the surface of the wafer W into the reaction products. In this case, through forced exhaust of the inside of the process chamber 41 by both of the exhaust mechanisms 100, 101 or one of the exhaust mechanisms 100, 101, the pressure in the process chamber 41 is reduced to about several tens mTorr to about several Torr, for instance. In such a low-pressure processing atmosphere, the natural oxide films 156 existing on the surface of the wafer W chemically react with molecules of the hydrogen fluoride gas and molecules of the ammonia gas to be turned into the reaction products.

When the chemical processing is finished, the supply of the hydrogen fluoride gas and the ammonia gas through the supply paths 81, 82 is stopped. Incidentally, the supply of the argon gas and the nitrogen gas through the supply paths 83, 84 may be stopped at the same time, but the supply of the argon gas and the nitrogen gas into the process chamber 41 through the supply paths 83, 84 may be continued even after the chemical processing is finished.

Then, the wafer W is moved from the first processing position to the second processing position. Specifically, the piston rod 63 is extended by the operation of the cylinder device 62 of the lifter mechanism 60, so that the wafer W is lifted up to the second processing position while the outer edge portion of the lower surface of the wafer W is housed in the stepped portion 61′ of the support member 61 as shown in FIG. 3. Consequently, the wafer W, the support member 61, and the partition member 70 partition the inside of the process chamber 41 into the space 41a above the wafer W and the space 41b under the wafer W. Incidentally, during this transfer of the wafer W from the first processing position to the second processing position, the inside of the process chamber 41 is also forcedly exhausted by both of the exhaust mechanisms 100, 101 or one of the exhaust mechanisms 100, 100 so that the pressure in the process chamber 41 is reduced to about several tens mTorr to about several Torr, for instance.

Next, the PHT (heat treatment) is started. In this heat treatment, the infrared rays are emitted from the lamp heater 72 into the process chamber 41 through the window portion 71 to heat the wafer W at the second processing position to a temperature equal to or higher than about 100° C., for instance. In this case, the wafer W can be rapidly heated to the target temperature since heat capacity of the wafer W itself is relatively small. Incidentally, the emission of the infrared rays by the lamp heater 72 may be started before the wafer W is moved to the second processing position.

Further, during the heat treatment, the upper space 41a in the process chamber 41 is forcedly exhausted by the exhaust mechanism 101 while the argon gas and the nitrogen gas are supplied into the process chamber 41 through the supply paths 83, 84, and reaction products 156′ produced by the aforesaid chemical processing are heated and vaporized to be removed from the inner surfaces of the recessed portions 155. In this case, since the inside of the process chamber 41 is partitioned by the wafer W, the support member 61, and the partition member 70 into the upper space 41a and the lower space 41b, the pressure of the upper space 41a is reduced to about several Torr to about several tens Torr, for instance, and the pressure of the lower space 41b is reduced to about several hundreds mTorr to about several Torr, for instance.

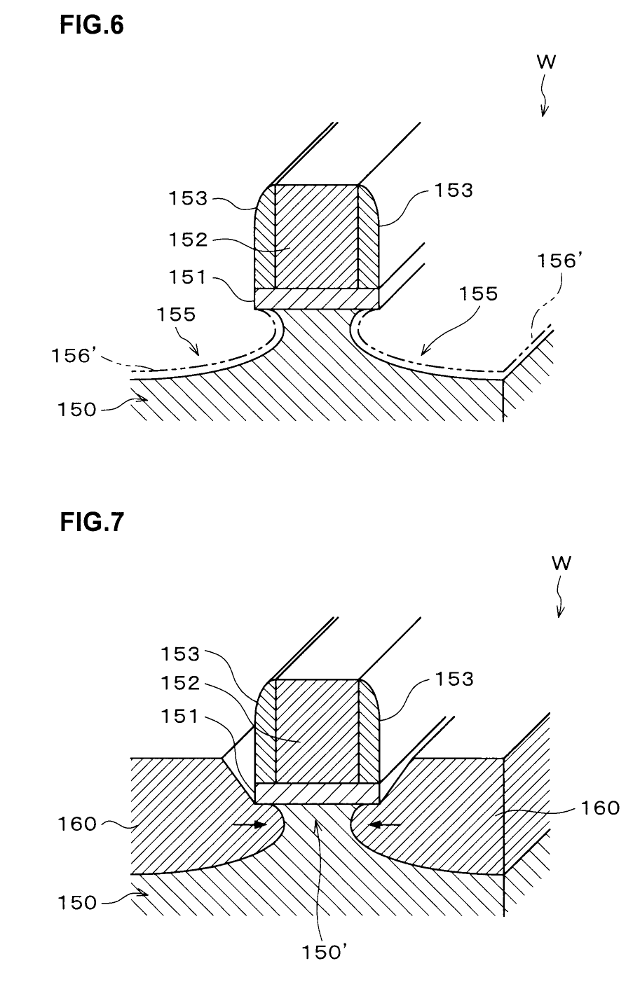

Through the above processes, the surface of the Si layer 150 is exposed by the heat treatment (see FIG. 6). Such PHT following the chemical processing makes it possible to dry-clean the wafer W and remove the natural oxide films 156 from the Si layer 150 by dry etching.

When the COR processing including the chemical processing and the heat treatment is finished, the supply of the argon gas and the nitrogen gas is stopped and the load/unload port 42 (gate valve 25) of the COR apparatus 22 is opened. Incidentally, the supply of the argon gas and the nitrogen gas into the process chamber 41 through the supply paths 83, 84 may be continued even after the COR processing is finished.

When the COR processing is finished, the lifter pins 55 move up from the mounting table 45, and the piston rod 63 is contracted by the operation of the cylinder device 62 of the lifter mechanism 60, so that the wafer W is moved down from the second processing position. Then, the wafer W is delivered to the lifter pins 55 from the support member 61 on its way downward. Thus, the wafer W is moved to the load/unload position.

Thereafter, the wafer W is carried out of the process chamber 41 by the wafer carrier mechanism 31, and then carried into the epitaxial growth apparatus 23. Incidentally, when the wafer W is carried out of the process chamber 41, the supply of the argon gas and the nitrogen gas into the process chamber 41 through the supply paths 83, 84 may be continued and the inside of the process chamber 41 may be forcedly exhausted by both of the exhaust mechanisms 100, 101 or one of the exhaust mechanisms 100, 101 so that the pressure in the process chamber 41 is reduced to about several Torr to about several tens Torr, for instance.

When the wafer W with the surface of the Si layer 150 being exposed by the COR processing is thus carried into the epitaxial growth apparatus 23, the SiGe film forming processing is then started. In the film forming processing, reaction gas supplied to the epitaxial growth apparatus 23 and the Si layer 150 exposed in the recessed portions 155 of the wafer W chemically react with each other, so that SiGe layers 160 are epitaxially grown on the recessed portions 155 (see FIG. 7). Here, since the natural oxide films 156 have been removed by the aforesaid COR processing from the surface of the Si layer 150 exposed in the recessed portions 155, the SiGe layers 160 are suitably grown with the surface of the Si layer 150 serving as their base.

When the SiGe layers 160 are thus formed on the recessed portions 155 on the both sides, a portion of the Si layer 150 sandwiched by the SiGe layers 160 is given a compressive stress from both sides. That is, under the Poly-Si layer 152 and the oxide layer 151, a strained Si layer 150′ having a compressive strain is formed in the portion sandwiched by the SiGe layers 160.

When the SiGe layers 160 are thus formed, that is, when the film forming processing is finished, the wafer W is carried out of the epitaxial growth apparatus 23 by the wafer carrier mechanism 31 to be carried into the load lock chamber 24. When the wafer W is carried into the load lock chamber 24, the load lock chamber 24 is airtightly closed and thereafter the load lock chamber 24 and the carrier chamber 12 are made to communicate with each other. Then, the wafer W is carried out of the load lock chamber 24 to be returned to the carrier C on the mounting table 13 by the wafer carrier mechanism 11. In the above-described manner, a series of processes in the processing system 1 is finished.

According to such a processing system 1, in the process chamber 41, the wafer W can be cooled and chemically processed on the mounting table 45 when it is at the first processing position, and the wafer W can be heated by the lamp heater 72 and heat-treated when it is at the second processing position. By thus moving the wafer W to the first processing position and to the second processing position in the process chamber 41, it is possible to rapidly heat and cool the wafer W. This enables rapid heat treatment, which can shorten the processing time to improve a throughput. Further, since the wafer W can be COR-processed in the same process chamber 41, the COR apparatus 22 can be compact and a complicated transfer sequence for transferring the wafer W is not required.

Further, during the heat treatment, the inside of the process chamber 41 is partitioned into the space 41a above the wafer W and the space 41b under the wafer W, and consequently, heat by the lamp heater 72 is not easily transferred to the lower space 41b, which can prevent a temperature increase of the mounting table 45 set in a lower area (an area under the partition member 70) in the process chamber 41. Accordingly, the mounting table 45 is kept in a state where it can easily cool the wafer W placed thereon next. In this case, if the partition member 70 is made of a heat insulating material, it is possible to more effectively prevent the temperature increase of the mounting table 45.

Since the upper space 41a in the process chamber 41 is forcedly exhausted by the exhaust mechanism 101 during the heat treatment, vapor of the reaction products 156′ vaporized from the surface of the wafer W can be discharged without entering the lower space 41b, which can prevent the reaction products 156′ from adhering again to a rear surface of the wafer W and the lower area in the process chamber 41 (the area under the partition member 70). In this case, the upper area in the process chamber 41 (the area above the partition member 70) becomes higher in temperature than the lower area in the process chamber 41 since the upper area is heated by the lamp heater 72, and therefore the reaction products 156′ are difficult to adhere to the upper area. Accordingly, the reaction products 156′ do not easily adhere to the entire process chamber 41, which makes it possible to keep the inside of the process chamber 41 clean.

In the foregoing, a preferred embodiment of the present invention is described, but the present invention is not limited to such an example. It is obvious that those skilled in the art could think of various modified examples and corrected examples within a range of the technical idea described in the claims, and it is understood that such examples naturally belong to the technical scope of the present invention.

In the above-described embodiment, the refrigerant channel 50 is shown as an example of the first temperature adjusting mechanism and the lamp heater 72 is shown as an example of the second temperature adjusting mechanism. However, as these first and second temperature adjusting mechanisms, any temperature adjusting mechanisms capable of heating or cooling can be used. In particular, the second temperature adjusting mechanism may be a heating mechanism provided in the middle of the N₂ supply path 84 in order to increase the temperature of the nitrogen gas. The nitrogen gas whose temperature has been increased may be jetted to the upper space 41a of the process chamber 41 from the showerhead 85 to heat the wafer W. Further, a heating mechanism may be provided in the Ar supply path 83. Further, the wafer W may be heated by the combination of the lamp heater 72 described in the above embodiment and the above heating mechanism. Further, though the COR apparatus 22 and its processing method are shown as an example of a substrate processing apparatus and a substrate processing method for processing a substrate, the present invention is applicable not only to such an apparatus and a method but also to other substrate processing apparatus and substrate processing method, for example, a substrate processing apparatus and a substrate processing method for applying, for example, an etching process, a CVD process, or the like to a substrate. Further, the substrate is not limited to the semiconductor wafer but may be, for example, a LCD substrate glass, a CD substrate, a printed circuit board, a ceramic substrate, and the like. Further, the processing system is not limited to the processing system 1 shown in FIG. 1, and the number and disposition of the processing apparatuses provided in the processing system may be any.

What is claimed is:

1. A substrate processing apparatus processing a substrate in a process chamber, the apparatus comprising:
a mounting table to have the substrate placed thereon in the process chamber;
a first temperature adjusting mechanism adjusting the temperature of the substrate placed on said mounting table;
a lifter mechanism lifting up the substrate from said mounting table in the process chamber; and
a second temperature adjusting mechanism adjusting the temperature of the substrate which has been lifted up from said mounting table by said lifter mechanism,
wherein said first temperature adjusting mechanism and said second temperature adjusting mechanism adjust the substrate to different temperatures respectively.

2. The substrate processing apparatus according to claim 1, further comprising
an exhaust mechanism exhausting the inside of the process chamber.

3. The substrate processing apparatus according to claim 2, further comprising
a partition member disposed around the substrate which has been lifted up from said mounting table by said lifter mechanism;
a first exhaust mechanism exhausting the inside of the process chamber above said partition member; and
a second exhaust mechanism exhausting the inside of the process chamber under said partition member.

4. The substrate processing apparatus according to claim 1, further comprising
a gas supply mechanism supplying predetermined gas to the inside of the process chamber.

5. The substrate processing apparatus according to claim 4,
wherein said gas supply mechanism supplies the predetermined gas to the inside of the process chamber above the substrate which has been lifted up from said mounting table by said lifter mechanism.

6. A substrate processing method of processing a substrate in a process chamber, the method comprising the steps of:
placing the substrate on a mounting table to process the substrate while adjusting the temperature of the substrate by a first temperature adjusting mechanism; and
lifting up the substrate from the mounting table in the process chamber to process the substrate while adjusting the temperature of the substrate by a second temperature adjusting mechanism,
wherein the first temperature adjusting mechanism and the second temperature adjusting mechanism adjust the substrate to different temperatures respectively.

7. The substrate processing method according to claim 6,
wherein the inside of the process chamber is exhausted.

8. The substrate processing method according to claim 6,
wherein predetermined gas is supplied to the inside of the process chamber.

9. A storage medium containing a recorded program executable by a control unit of a substrate processing apparatus,
the program causing the substrate processing apparatus to perform the substrate processing method according to claim 6 when executed by the control unit.
